(19) United States
(12) Patent Application Publication
(10) Pub. No.: US 2025/0345747 A1
(43) Pub. Date: Nov. 13, 2025

(54) FLUORINATED GAS ABATEMENT AND FLUORIDE SEQUESTRATION USING SILICON

(71) Applicant: International Business Machines Corporation, Armonk, NY (US)

(72) Inventors: Teodor Krassimirov Todorov, Yorktown Heights, NY (US); Jed Pitera, Portola Valley, CA (US); Fausto Martelli, Stockton Heath (GB)

(21) Appl. No.: 18/659,625

(22) Filed: May 9, 2024

(51) Int. Cl. B01D 53/76; B01D 53/34; B01D 53/38; C01B 9/08; C01B 33/027; H01L 21/67

(52) U.S. Cl. CPC B01D 53/76; B01D 53/346; B01D 53/38; C01B 9/08; C01B 33/027; H01L 21/67017; B01D 2251/304; B01D 2251/606; B01D 2253/106; B01D 2253/1122; B01D 2257/204; B01D 2258/0216

(57) ABSTRACT

A process includes providing a reactor containing a compound of the formula SiOₓ, wherein 0≤x≤2, and receiving, at the reactor, fluorinated gas. The process also includes obtaining a gaseous mixture formed at an elevated temperature in the reactor and removing silicon tetrafluoride from the gaseous mixture. An apparatus includes a reactor containing a compound of the formula SiOₓ, wherein 0≤x≤2, a component for receiving fluorinated gas at the reactor, a heating element for heating the compound of the formula SiOₓ and the fluorinated gas in the reactor, and a separation component for removing silicon tetrafluoride from a gaseous mixture formed in the reactor. A process of semiconductor manufacturing includes defluorinating exhaust gas using the process. A system for semiconductor manufacturing includes a set of components for carrying out the process.

### BACKGROUND

The present disclosure relates to reactions of halogenated compounds and, more specifically, to abatement of fluorinated gas.

In semiconductor manufacturing, fluorinated and other process gases provide selectivity and specificity in processes such as etching, deposition, and chamber cleaning. Fluorinated gases are used to pattern semiconductor wafers and multiple material layers thereon, predominantly containing silicon or silicon compounds. The resultant exhaust gas contains a small fraction of silicon tetrafluoride (SiF₄) and a larger fraction of unreacted or partially reacted fluorinated compounds.

### SUMMARY

Various embodiments are directed to a process that includes receiving fluorinated gas at a reactor containing a compound of the formula SiOₓ, wherein 0≤x≤2. The process also includes obtaining a gaseous mixture formed at an elevated temperature in the reactor and removing silicon tetrafluoride from the gaseous mixture.

Additional embodiments are directed to an apparatus that includes a reactor containing a compound of the formula SiOₓ, wherein 0≤x≤2, a component for receiving fluorinated gas at the reactor, a heating element for heating the compound of the formula SiOₓ and the fluorinated gas in the reactor, and a separation component for removing silicon tetrafluoride from a gaseous mixture formed in the reactor.

Further embodiments are directed to a system with an apparatus that includes a reactor containing a compound of the formula SiOₓ, wherein 0≤x≤2, a component for receiving fluorinated gas at the reactor, a heating element for heating the compound of the formula SiOₓ and the fluorinated gas in the reactor, and a separation component for removing silicon tetrafluoride from a gaseous mixture formed in the reactor.

Additional embodiments are directed to a process of semiconductor manufacturing involving defluorinating exhaust gas using a process that includes receiving fluorinated gas at a reactor containing a compound of the formula SiOₓ, wherein 0≤x≤2. The process also includes obtaining a gaseous mixture formed at an elevated temperature in the reactor and removing silicon tetrafluoride from the gaseous mixture.

Further embodiments are directed to a system for semiconductor manufacturing that includes a set of components configured to carry out a process of fluorinated gas abatement. This process includes receiving fluorinated gas at a reactor containing a compound of the formula SiOₓ, wherein 0≤x≤2. The process also includes obtaining a gaseous mixture formed at an elevated temperature in the reactor and removing silicon tetrafluoride from the gaseous mixture.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1A is a flow diagram illustrating a process of fluorinated gas abatement, according to some embodiments.

FIG. 1B is a flow diagram illustrating a computer-implemented method of optimizing fluorinated gas abatement, according to some embodiments.

FIG. 2A is a block diagram illustrating a system for fluorinated gas abatement using metal vapor and silica, according to some embodiments.

FIG. 2B is a block diagram illustrating a system for fluorinated gas abatement using elemental silicon, according to some embodiments.

FIG. 2C is a block diagram illustrating a system for fluorinated gas abatement during semiconductor processing, according to some embodiments.

FIGS. 3A and 3B are cross-sectional diagrams illustrating examples of metal vapor sources for fluorinated gas abatement, according to some embodiments.

FIGS. 4A and 4B are cross-sectional diagrams illustrating apparatuses for fluorinated gas abatement, according to some embodiments.

FIG. 5 is a block diagram illustrating a computing environment, according to some embodiments.

While the invention is amenable to various modifications and alternative forms, specifics thereof have been shown by way of example in the drawings, and will be described in detail. It should be understood, however, that the intention is not to limit the invention to the particular embodiments described. Instead, the intention is to cover all modifications, equivalents, and alternatives falling within the spirit and scope of the invention.

### DETAILED DESCRIPTION

Embodiments of the present invention are generally directed to reactions of halogenated compounds and, more specifically, to abatement of fluorinated compounds in exhaust gas. While the present disclosure is not necessarily limited to such applications, various aspects of the disclosure may be appreciated through a discussion of examples using this context.

Although the present invention has been described in reference to specific embodiments, it should be understood that the invention is not limited to these examples only and that many variations of these embodiments may be readily envisioned by the skilled person after having read the present disclosure. The invention may thus further be described without limitation, and by way of example only, by the following embodiments.
Embodiment 1: a process comprising receiving fluorinated gas at a reactor containing a compound of the formula SiOₓ, wherein 0≤x≤2, obtaining a gaseous mixture formed at an elevated temperature in the reactor, and removing silicon tetrafluoride (SiF₄) from the gaseous mixture. This process can have the technical benefit of scrubbing fluorinated compounds from the gas in a way that can allow capture and use of SiF₄ formed in the scrubbing.
Embodiment 2: the process of embodiment 1, wherein 0≤x≤0.1. This formula indicates that the compound SiOₓ is substantially elemental silicon, which advantageously acts as a scrubbing agent for fluorinated compounds in the gas.
Embodiment 3: the process of embodiment 1 or 2, wherein the elevated temperature is between about 960° C. and 1100° C. These temperatures can optimize the reactivity of the fluorinated compounds with the SiOₓ compound.
Embodiment 4: the process of any one of embodiments 1-3, wherein removing the SiF₄ comprises wet scrubbing. The use of wet scrubbing to remove the SiF₄ can be advantageous when integrating the process into an existing system.
Embodiment 5: the process of any one of embodiments 1-3, wherein removing the SiF₄ comprises passing the gaseous mixture through sodium bicarbonate or sodium fluoride to form sodium fluorosilicate. An advantage of this is that relatively low-cost materials can be used to mitigate the toxicity of SiF₄ and convert it to a synthetically useful compound.
Embodiment 6: the process of embodiment 5, further comprising using the sodium fluorosilicate to produce a fluoride. This can advantageously recycle the fluorine from the fluorinated compounds and form fluorides, which are useful compounds in a wide variety of applications.
Embodiment 7: the process of embodiment 5, further comprising using sodium fluorosilicate to produce high-purity silicon. A benefit of this is that the SiOₓ can be recycled to form silicon used in the semiconductor industry.
Embodiment 8: the process of any one of embodiments 1 and 3-7, wherein the compound of the formula SiOₓ comprises silica. Advantages of silica can include its low cost and versatility.
Embodiment 9: the process of embodiment 8, wherein the reactor also contains zinc vapor. The zinc vapor may promote conversion of the fluorinated compounds and silica to SiF₄.
Embodiment 10: the process of any one of embodiments 1-9, further comprising monitoring abatement of the fluorinated gas using at least one sensor, generating a machine-learning model for modeling the abatement, and based on the monitoring and the machine-learning model, generating instructions for optimizing the abatement.
Embodiment 11: an apparatus, comprising a reactor containing a compound of the formula SiOₓ, wherein 0≤x≤2, a component for receiving fluorinated gas at the reactor, a heating element for heating the compound of the formula SiOₓ and the fluorinated gas in the reactor, and a separation component for removing silicon tetrafluoride (SiF₄) from a gaseous mixture formed in the reactor. This apparatus can have the technical benefit of scrubbing fluorinated compounds from the gas in a way that can allow capture and use of SiF₄ formed in the scrubbing.
Embodiment 12: the apparatus of embodiment 11, wherein 0≤x≤0.1. This formula indicates that the compound SiOₓ is substantially elemental silica, which advantageously acts as a scrubbing agent for fluorinated compounds in the gas.
Embodiment 13: the apparatus of embodiment 11 or 12, wherein the elevated temperature is between about 960° C. and 1100° C. These temperatures can optimize the reactivity of the fluorinated compounds with the SiOₓ compound.
Embodiment 14: the apparatus of any one of embodiments 11-13, wherein the separation component comprises a scrubber containing sodium bicarbonate or sodium fluoride. An advantage of this is that relatively low-cost materials can be used to mitigate the toxicity of SiF₄ and convert it to synthetically useful compounds.
Embodiment 15: the apparatus of any one of embodiments 11-14, wherein 1.5≤x≤2. This formula indicates that the compound SiOₓ is substantially silica. Advantages of silica can include its low cost and versatility.
Embodiment 16: the apparatus of embodiment 15, further comprising a metal vapor source.
Embodiment 17: the apparatus of embodiment 16, further comprising a mixing component for mixing the metal vapor with the fluorinated gas.

A technical benefit of embodiments 16 and 17 can be that zinc vapor may promote conversion of the fluorinated compounds and silica to SiF₄.
Embodiment 18, the apparatus of any one of embodiments 11-17, wherein the fluorinated gas is an exhaust gas from semiconductor processing. Semiconductor processing is a major source of fluorinated gas, and the apparatus has the technical benefit of abating this gas.
Embodiment 19: the apparatus of any one of embodiments 11-18, wherein the apparatus is monitored by at least one sensor in communication with a computing device. This can have the technical benefit of allowing greater control over processes involving the apparatus.
Embodiment 20: the apparatus of embodiment 19, wherein the computing device is configured to generate a machine-learning model for modeling a process of fluorinated gas abatement, and based on the monitoring and the machine-learning model, generate instructions for the apparatus. This can have the technical benefit of applying machine learning to optimize fluorinated gas abatement using the apparatus.
Embodiment 21: a system, comprising: an apparatus that comprises a reactor containing a compound of the formula SiOₓ, wherein 0≤x≤2, a component for receiving fluorinated gas at the reactor, a heating element for heating the compound of the formula SiOₓ and the fluorinated gas in the reactor, and a separation component for removing silicon tetrafluoride (SiF₄) from a gaseous mixture formed in the reactor. This apparatus can have the technical benefit of scrubbing fluorinated compounds from the gas in a way that can allow capture and use of SiF₄ formed in the scrubbing.
Embodiment 22: a process of semiconductor manufacturing comprising defluorinating exhaust gas using a process that includes receiving fluorinated gas at a reactor containing a compound of the formula SiOₓ, wherein 0≤x≤2, obtaining a gaseous mixture formed at an elevated temperature in the reactor, and removing silicon tetrafluoride (SiF₄) from the gaseous mixture. This process can have the technical benefit of scrubbing fluorinated compounds from the exhaust gas in a way that can allow capture and use of SiF₄ formed in the scrubbing.
Embodiment 23: the process of embodiment 22, wherein removing the SiF₄ comprises passing the gaseous mixture through sodium bicarbonate or sodium fluoride. An advantage of this is that relatively low-cost materials can be used to mitigate the toxicity of SiF₄ and convert it to a synthetically useful compound.
Embodiment 24: a system for semiconductor manufacturing that includes a set of components configured to carry out a process of fluorinated gas abatement. The process of fluorinated gas abatement includes providing a reactor containing a compound of the formula SiOₓ, wherein 0≤x≤2, receiving, at the reactor, fluorinated gas, obtaining a gaseous mixture formed at an elevated temperature in the reactor, and removing silicon tetrafluoride (SiF₄) from the gaseous mixture. This process can have the technical benefit of scrubbing fluorinated compounds from the exhaust gas in a way that can allow capture and use of SiF₄ formed in the scrubbing.
Embodiment 25: the system embodiment 24, further comprising a computing device configured to generate instructions for at least one component from the set of components based on a machine-learning model for modeling the process of fluorinated gas abatement. This can have the technical benefit of applying machine learning to optimize fluorinated gas abatement.

Various embodiments of the present disclosure are described herein with reference to the related drawings, where like numbers refer to the same component. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “over,” “positioned on,” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

As used herein, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

Unless otherwise noted, ranges (e.g., time, concentration, temperature, etc.) indicated herein include both endpoints and all numbers between the endpoints. Unless specified otherwise, the use of a tilde (˜) or terms such as “about,” “substantially,” “approximately,” “slightly less than,” and variations thereof are intended to include the degree of error associated with measurement of the particular quantity based upon the equipment available at the time of filing the application. For example, “about” can include a range of ±8% or 5%, or 2% of a given value, range of values, or endpoints of one or more ranges of values. Unless otherwise indicated, the use of terms such as these in connection with a range applies to both ends of the range (e.g., “approximately 1 g-5 g” should be interpreted as “approximately 1 g-approximately 5 g”) and, in connection with a list of ranges, applies to each range in the list (e.g., “about 1 g-5 g, 5 g-10 g, etc.” should be interpreted as “about 1 g-about 5 g, about 5 g-about 10 g, etc.”).

As described herein, compounds of the present disclosure can optionally be substituted with one or more substituents or as exemplified by particular classes, subclasses, and species of the present disclosure. As described herein, any of the above moieties or those introduced below can be optionally substituted with one or more substituents described herein.

The term “substituted” in the context of the present disclosure means that one or more hydrogen atoms of the indicated radical or group is/are independently replaced by the same or a different substituent(s). Additionally, the term “substituted” specifically provides for one or more, e.g., two, three, or more, substituents commonly used in the art. However, it is generally known that the substituents should be selected so that they do not adversely affect the useful properties of the compound or its function.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, in general, in semiconductor manufacturing, fluorinated and other process gases provide selectivity and specificity in processes such as etching, deposition, and chamber cleaning. Fluorinated compounds (e.g., tetrafluoromethane (CF₄), trifluoromethane (CHF₃), per- and polyfluoroalkyl substances (PFAS), etc.) are used to pattern semiconductor wafers and multiple materials layers thereon, predominantly containing silicon or silicon compounds. The resulting exhaust contains a small fraction of silicon tetrafluoride (SiF₄) and a larger fraction of unreacted or partially reacted fluorinated compounds. The favorable action of the plasma on the conversion of silicon (Si) or Si compounds to SiF₄ is explained by the concept of “hot electrons”, wherein electrons behave as if the process is carried out at elevated temperature.

Gases containing fluorinated compounds are major components of direct (scope 1) and indirect (scope 2) greenhouse emissions for semiconductor fabrication plants (“fabs”). Some of these fluorinated compounds (e.g., NF₃) are reactive and can be reliably scrubbed from the exhaust of fabrication tools. However, many of the fluorinated compounds used in significant quantities (e.g., fluorocarbons such as CF₄, CHF₃, etc.) are relatively inert and therefore difficult to capture or recover. Scrubbing systems for SiF₄ are currently mandatory in most industrial applications, with wet scrubbing being a common practice.

Specific hurdles to abatement of gaseous fluorocarbons, PFAS, and other fluorinated compounds include their high fugacity, high stability, low polarity, and low solubility in water. Additionally, the reuse of captured fluorinated gases in semiconductor manufacturing can be hindered by the extreme purity requirements of this industry. For example, the evolution of contaminants during wafer processing and the low volumes of gases recovered using existing techniques can limit the effectiveness of on-site purification and reuse installations.

Consequently, destructive approaches are commonly employed to eliminate fluorinated gases and other exhaust gases (e.g., chlorinated gases). Given the toxicity and flammability of byproducts in the semiconductor exhaust gas mixtures, the byproducts are often subjected to incineration followed by scrubbing of soluble species. This process aims to convert the exhaust mixture into smaller species readily scrubbed by water or alkaline solutions.

While chlorinated compounds can be converted in this process, the high stability of carbon-fluorine (C—F) bonds makes it difficult to break down fluorocarbons by this approach. CF₄ is considered to be particularly resilient to incineration, requiring temperatures in excess of 1400° C. This resilience to abatement is due to the fact that C—F bonds are the strongest in organic chemistry and are further strengthened by each additional fluorine atom, 4 being the maximum. Consequently, attempts to abate larger PFAS molecules by industry-standard incineration methods in most cases leads to the formation of CF₄ as a biproduct. Fluorocarbon destruction using plasma and/or catalyst-assisted approaches have been proposed, but require significant investment in equipment and energy, further increasing the carbon footprint of the fab.

Other approaches can include separation of fluorinated species from exhaust gas followed by further refinement on a larger scale, e.g., at a waste treatment facility. Separation techniques can include cryogenic liquefaction and distillation of fluorinated constituents, continuous chromatography, membrane separation, and solid sorbents. Other separation techniques can include absorption into a carrier liquid or into a porous carbon or metal organic framework. A disadvantage of these absorption strategies can be that fluorination imparts solution properties significantly different from typical hydrocarbons. To facilitate absorption of fluorocarbons, the absorption medium itself may have to be chemically fluorinated to enhance the interaction energies between the target gases and the medium.

Embodiments of the present disclosure may overcome these and other disadvantages of current techniques for fluorinated gas abatement. In some embodiments, a gas that includes fluorinated compounds (“fluorinated gas”) can be mixed with elemental silicon or silicon compounds, such as silica, at elevated temperatures (e.g., about 960-1100° C.). Herein, silicon, silica, and mixtures thereof are collectively referred to using the formula SiOₓ, where x is greater than or equal to zero (e.g., 0≤x≤2). Reactions between the fluorinated compounds and SiOₓ can form SiF₄ and carbon (e.g., nanoparticles, graphene, amorphous, etc.). Upon condensation, the carbon can be removed from the defluorinated gas by filtration. The SiF₄ may be reacted with sodium bicarbonate (NaHCO₃) or sodium fluoride (NaF) to form sodium fluorosilicate (Na₂SiF₆), although other scrubbing methods may also be used to remove the SiF₄. The Na₂SiF₆ may be used to generate high-purity SiF₄, which may be converted to fluorides and/or silicon (e.g., high-purity polycrystalline silicon for semiconductor applications). This can allow recycling of the fluorine from semiconductor exhaust. In some embodiments, substantially all of the fluorine may be recycled.

In other embodiments, the fluorinated gas may be mixed with metal vapor in addition to SiOₓ. For example, a gaseous fluorocarbon may be reacted with zinc (e.g., zinc vapor) and silica to form zinc oxide (ZnO), carbon, and SiF₄, The ZnO and carbon may be isolated as solids, and the SiF₄ may be removed by scrubbing as discussed above. Metals such as Zn can be more suitable for defluorination than alkali metals and alkaline earth metals because of the high reactivity of alkali and alkaline earth metals. The high reactivity can cause excess condensation of metal in the reaction product and make it difficult and expensive to handle the alkali and alkaline earth metals safely, particularly on a large scale.

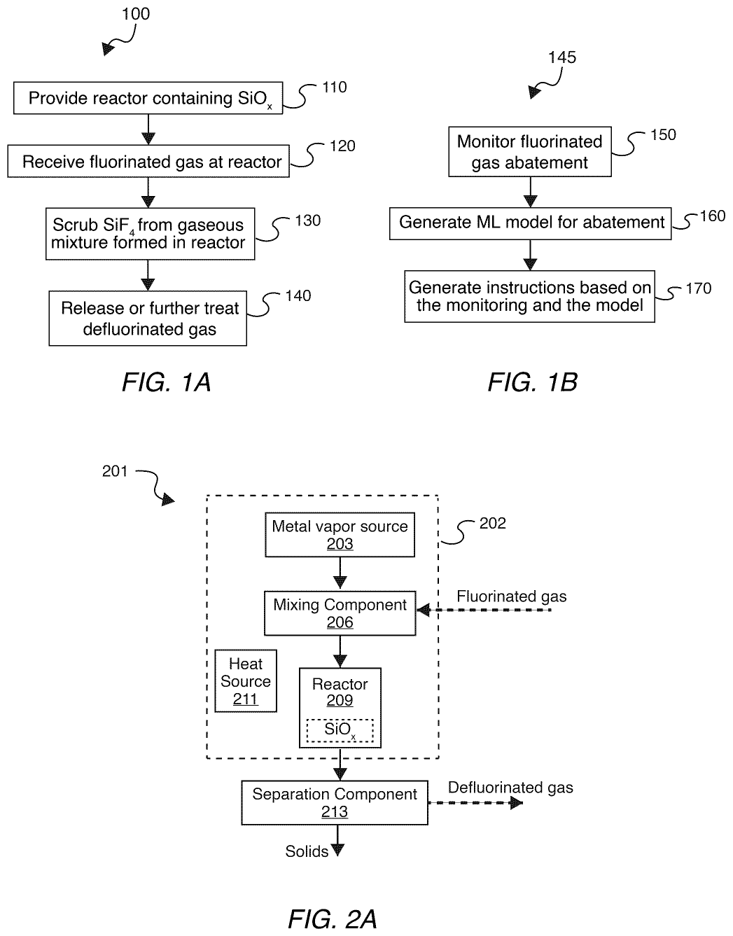

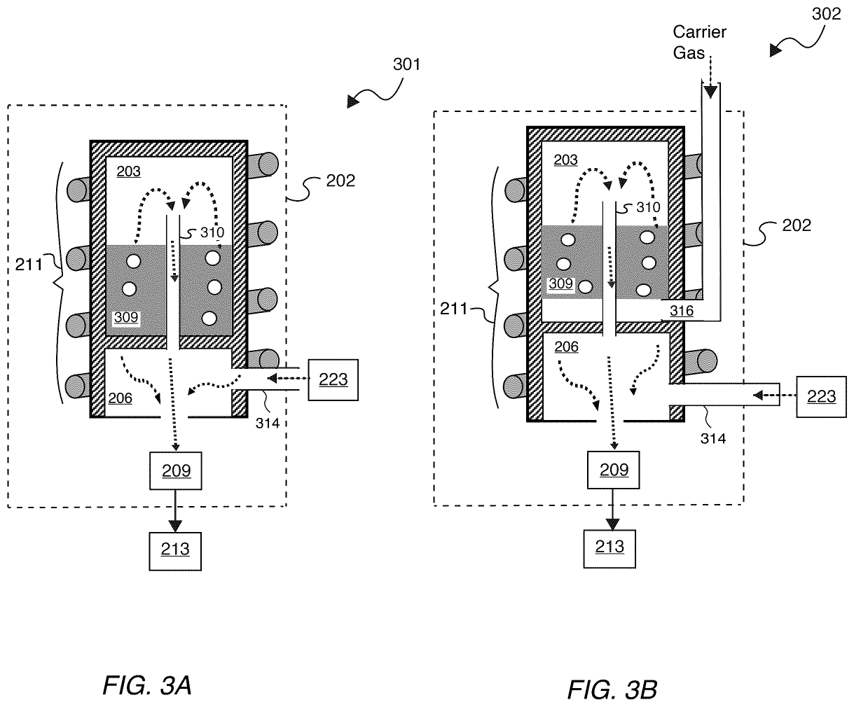

Referring now to the drawings, in which like numerals represent the same or similar elements, FIG. 1A is a flow diagram illustrating a process 100 of fluorinated gas abatement, according to some embodiments. A reactor containing SiOₓ can be provided. This is illustrated at operation 110. In some embodiments, the reactor contains substantially pure elemental silicon (e.g., SiOₓ where x=0-0.1) or primarily elemental silicon (e.g., SiOₓ where x=0.1-0.5). In further embodiments, the reactor can contain a mixture of silica (e.g., SiOₓ where x=˜ 2) and metal (e.g., zinc) vapor from a metal vapor source (see FIGS. 3A and 3B). However, any appropriate composition of SiOₓ and, optionally, metal vapor may be provided in the reactor. The SiOₓ can be in any appropriate form with sufficient surface area (e.g., particles with average sizes ranging from 1 nm to 1 mm). In some embodiments, the SiOₓ in the reactor can include silicon granules, silicon nanoparticles, silicon powder, silicon pellets, silicon wool, silicon sponge, silicon shavings, etc. In further embodiments, such as when metal vapor is used, the SiOₓ in the reactor can be a material such as silica sand, silica nanoparticles, silica powder, porous or mesoporous silica, etc.

The reactor can receive fluorinated gas from a fluorinated gas source. This is illustrated at operation 120. The fluorinated gas may be an exhaust gas from semiconductor processing. In some embodiments, the fluorinated exhaust gas may be treated by, e.g., removing other components of the exhaust gas before entering the reactor. The reactions taking place in the reactor can be carried out at elevated temperatures (e.g., about 960-1100° C.). When the reactor contains primarily elemental silicon (e.g., SiOₓ where x=0-0.5), fluorinated compounds in the fluorinated gas can react with the SiOₓ to form SiF₄ and carbon. When a metal vapor and primarily silica (e.g., SiOₓ where x=1-2) are used, the fluorinated compounds in the exhaust gas can react with the metal vapor and SiOₓ to form a metal oxide, carbon, and SiF₄. In some embodiments, these products can be passed through substantially pure silicon in order to convert any unreacted fluorinated compounds into SiF₄.

SiF₄ can be removed (scrubbed) from a gaseous mixture formed in the reactor. This is illustrated at operation 130. The gaseous mixture formed in the reactor can include products of reactions between the fluorinated compounds received at operation 120, SiOₓ, and, optionally, metal vapor. In some embodiments, the gaseous mixture formed in the reactor can travel from the reactor into a lower-temperature component (e.g., a cooling and/or separation component) that allows condensation of products such as carbon and fluorides during or prior to scrubbing.

Various SiF₄-scrubbing agents/techniques can be used at operation 130. For example, the gaseous mixture formed in the reactor can be passed through NaHCO₃ or NaF, which can convert the SiF₄ into Na₂SiF₆. SiF₄ can be absorbed by solid NaF at or below about 300° C. (e.g., about 100-300 C). Desorption may take place at or above about 600° C. In some embodiments, particularly when NaF is used, this scrubbing process may optionally be carried out under vacuum.

The Na₂SiF₆ may be used to generate high-purity SiF₄, which may be converted to fluoride (F⁻) compounds (e.g., hydrogen fluoride, sodium fluoride, metal fluorides, etc.). For example, fluorides may be produced via hydrolysis reactions in liquid or vapor phase. The fluorides may be high-purity fluorides (e.g., at least 99.99-99.999% purity). This can allow recycling of the fluorine from semiconductor exhaust. The Na₂SiF₆, or SiF₄ generated by its thermal decomposition, may also be used to generate silicon (e.g., high-purity polycrystalline silicon for semiconductor applications).

Other scrubbing methods known in the art may be used to remove SiF₄ in some embodiments. For example, the gaseous mixture may be treated by wet scrubbing. Wet scrubbing can include using hydrofluoric acid to convert the SiF₄ to hexafluorosilicic acid (H₂SiF₆), which may optionally be used for water fluorination or production of fluorine derivatives such as HF that can be optionally reused in a circular process in the semiconductor industry.

The defluorinated exhaust gas can then be released or treated further (e.g., to remove other components of the exhaust gas). This is illustrated at operation 140. Herein, “defluorinated gas” and “defluorinated exhaust gas” refer to gases (including gaseous mixtures) having lower concentrations of fluorinated compounds relative to their concentrations before fluorinated gas abatement (e.g., operations 110-130). In some embodiments, the percent abatement of the fluorinated gas is greater than about 50%. In further embodiments, the defluorinated gas may be substantially free from fluorinated compounds, e.g., wherein the percent abatement is about 95-99%, 98-99%, 99-99.99%, or higher.

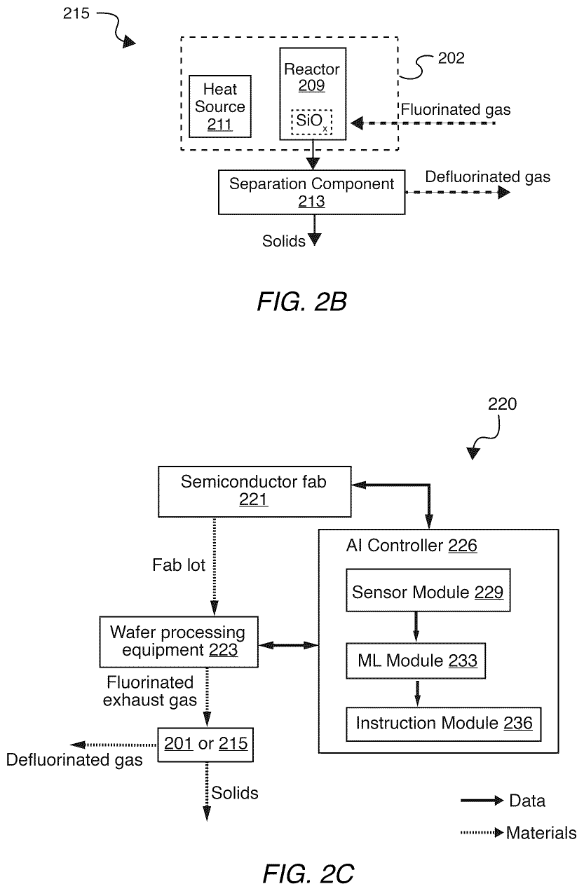

FIG. 1B is a flow diagram illustrating a computer-implemented method 145 of optimizing fluorinated gas abatement, according to some embodiments. The process of fluorinated gas abatement (e.g., process 100) can be monitored. This is illustrated at operation 150. A machine-learning model that models the process of abatement can be generated. This is illustrated at process 160. Based on the monitoring and the model, suggestions, insights, and/or instructions for carrying out the process, e.g., with more efficiency, can be generated. This is illustrated at operation 170. Process 145 is discussed in greater detail below with respect to FIG. 2C.

FIG. 2A is a block diagram illustrating a system 201 for fluorinated gas abatement using metal vapor and silica, according to some embodiments. FIG. 2B is a block diagram illustrating a system 215 for fluorinated gas abatement using elemental silicon, according to some embodiments. Where components of systems 201 and 215 can be substantially similar, the same reference numbers are used.

System 201 contains thermally isolated components 202 including a metal vapor source 203, a mixing component 206, reactor 209, and a heat source 211. The metal vapor source 203 can introduce metal (e.g., zinc) vapor into a mixing component 206 where it can be mixed with fluorinated gas at an elevated temperature (e.g., at operation 120 of process 100). In some embodiments, the mixing component 206 has a geometry similar to devices used for gas combustion, e.g., a gas torch-style mixer. However, any appropriate mixing components may be used, such as high-velocity jets, vortex mixers, etc. In system 201, the mixing component 206 can receive fluorinated gas.

The fluorinated gas can be from a fluorinated gas source (not shown in FIGS. 2A and 2B), which may include semiconductor processing equipment. This is discussed in greater detail with respect to FIG. 2C. The fluorinated gas/metal vapor mixture from the mixing component 206 can enter a reactor 209 at the elevated temperature. In some embodiments, this is facilitated by reduced pressure in the reactor 209. The reactor 209 can contain silica (e.g., in the form of sand). In some embodiments, the reaction mixture may be passed through elemental silicon (not shown in FIG. 2A) after the silica in order to remove potentially unreacted fluorinated compounds.

System 215 contains thermally isolated components 202 including a reactor 209 and a heat source 211. In system 215, fluorinated gas from a fluorinated gas source can be received by a reactor 209 where it is combined with elemental silicon (e.g., SiOₓ where x=0-0.5) at an elevated temperature (e.g., at operation 120 of process 100).

Any appropriate reactor 209 may be used in systems 201 and 215, such as a homogeneous volume reactor, packed bed reactor containing a catalyst or consumable reagent, etc. Any appropriate heat source 211 can be used to heat the thermally isolated components 202 of systems 201 and 215. Examples of heat sources 211 that may be used can include direct resistive, inductive, and/or microwave heating. In some embodiments, more than one heat source is used. For example, the metal vapor source 203 of system 201 may have its own heat source, such as a graphite boiler, tubular/crucible furnace, electric melting furnace, etc.

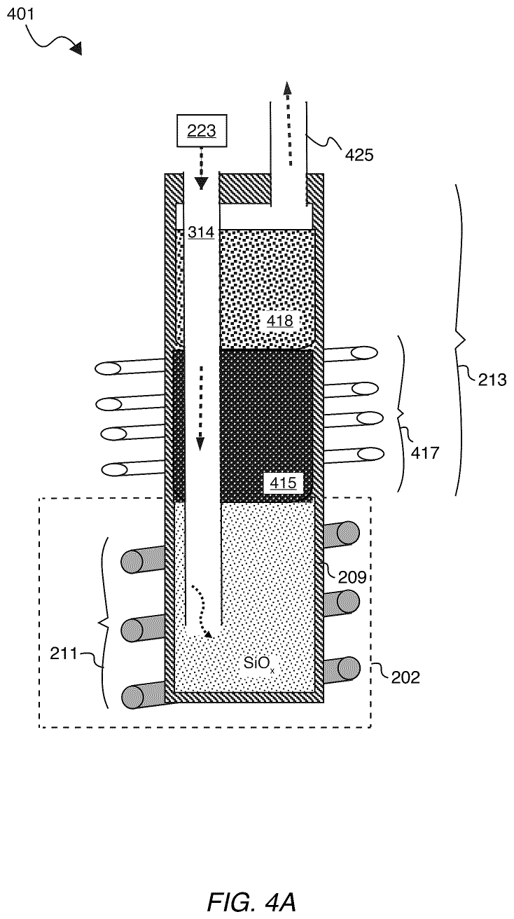

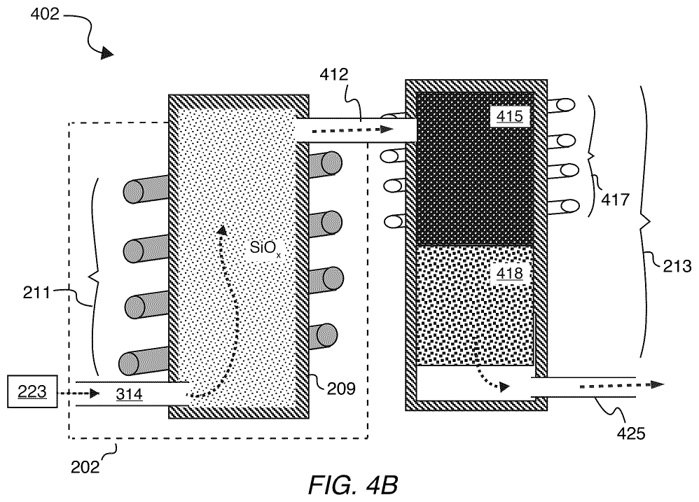

Systems 201 and 215 can each include a separation component 213 for separation of products and other materials from the defluorinated gas. The separation component 213 can include one or more chambers, filters, reagents, etc. For example, solids such as zinc oxide, zinc fluoride, excess zinc, and carbon can be condensed in a cooling chamber of the separation component in system 201. In system 215, a cooling component may be used to condense carbon. In some embodiments, the separation component 213 uses a coolant to facilitate condensation in a cooling chamber, reaction chamber, filtration component, etc. In other embodiments, the precipitation chamber and/or other parts of the separation component 213 may be at ambient temperature. The precipitation chamber may include other components, such as a carbon filter (see, e.g., FIGS. 4A and 4B).

The separation component 213 may include a filter, cyclone, chemical absorbent, physical absorbent, and/or other components for isolating, reacting, and/or purifying the condensed materials. For example, a cyclone and/or a sleeve filter may be used to aid separation of the condensed materials from the defluorinated gas. The separation component 213 may be integrated with a commercially available stainless steel bag filter housing. In some embodiments, additional reagents in solid (e.g., silica or silicon), gaseous, or liquid phase, as well as chemical (e.g., NaHCO₃ or NaF) and/or physical absorbents can be used to facilitate efficient PFAS abatement and/or separation of the reaction products to obtain defluorinated exhaust gas. In system 201, the separation component may also be used to remove excess metal. For example, excess condensed Zn may be removed by evaporation at about 907° C. The zinc may be collected and optionally recycled.

In both systems 201 and 215, the separation component 213 can use NaHCO₃ or NaF to scrub SiF₄ produced by the reactions with SiOₓ. The reaction with NaHCO₃ or NaF can form Na₂SiF₆. Using NaF rather than NaHCO₃ can prevent the production of carbon dioxide (CO₂) as a biproduct of the scrubbing and may allow the scrubbing to take place under vacuum. While NaHCO₃ and NaF are illustrated herein, any appropriate compound for reacting with SiF₄ to form Na₂SiF₆ may be used in system 201 or 215.

Other scrubbing methods known in the art may be used to remove SiF₄ in some embodiments. For example, wet scrubbing, gas dilution, or other techniques known in the art may be used to remove SiF₄ before releasing the gas. These may be used instead of, or in addition to, reactants for forming Na₂SiF₆. The defluorinated gas can be released or treated further (e.g., at operation 140 of process 100).

FIG. 2C is a block diagram illustrating a system 220 for fluorinated gas abatement during semiconductor processing, according to some embodiments. In FIG. 2C, dashed arrows indicate the movement of materials between components of system 220, and solid arrows indicate the movement of data between components of system 220. A wafer lot 221 from a semiconductor fab can be provided for production of integrated circuits by wafer processing equipment 223. The wafer processing equipment 223 can include tools for plasma etching. The plasma etching can use fluorinated compounds (e.g., CF₄, PFAS, etc.) to pattern semiconductor wafers and other material layers thereon, predominantly containing SiOₓ. The fluorinated exhaust gas can be transferred to system 201 or 215 (FIGS. 2A and 2B, respectively). More specifically, the fluorinated exhaust gas can be transferred to the mixing component 206 of system 201 or the reactor 209 of 215. The exhaust gas can be processed by system 201 or 215, e.g., according to process 100 (FIG. 1), in order to remove the fluorinated gas. The defluorinated exhaust gas can then be released or treated further.

System 220 can also include an artificial intelligence (AI)-based controller (“AI controller”) 226 in some embodiments. In other embodiments, the AI controller 226 may be omitted. The AI controller 226 may be used in process 100 to, e.g., favor a desired reaction by generating instructions for adjusting the composition of the fluorinated gas, reagents, and/or sorbent columns. In some embodiments, AI controller 226 can facilitate process 100 by carrying out worldwide literature searches, monitoring processes and operations of system 220, and generating experimental adjustments for process 100.

The AI controller 226 can include a sensor module 229 that receives data from sensors at the wafer processing equipment 223 and/or system 201 or 215 (e.g., at operation 150 of process 145). Examples of sensors that may be used can include inline flow meters, Fourier-transform infrared (FTIR) spectroscopy modules, mass spectrometers, temperature sensors, digital cameras, microscopes, optical sensors, and/or electrical current sensors. The sensors are not illustrated in FIG. 2C.

The sensor data can be input into a machine learning (ML) model 233 generated to simulate the abatement process (e.g., at operation 160 of process 145). In some embodiments, the ML model 233 receives real-time sensor data (from the sensor module 229) or AI-derived values of materials and energy flows, which may be compiled in a digital twin (not shown) of system 220 or system 201/215. For example, the AI controller 226 may use the digital twin for optimizing process 100 to reduce chemical, water, and energy consumption based on operational learning from the process flows. Based on the sensor data and/or other input information (see below), the ML model 233 can predict actions likely to benefit the abatement process. Instructions based on these predictions may be provided to the semiconductor fab, wafer processing equipment 223, and/or system 201/215 (e.g., at operation 170 of process 145) via the instruction module 236.

Optionally, systems 220 and/or 201 or 215 can be equipped with a variety of modules (not shown), such as multiple sources of gas (e.g. metal vapor, oxygen, hydrogen, water, natural gas, etc.), solid (e.g. sand, metals, etc.), and/or liquid reagents and sorbents (e.g. water, NaOH scrubbing solutions, etc.), as well as multiple reactor or separation units (e.g. furnace, gas jet, packed bed, wet scrubber, etc.). The AI controller 226 may be used to choose these modules individually or in different combinations and/or sequences. In some embodiments, automatic adjustments may be made via these modules in response to instructions from the instruction module 236 (see below).

In some embodiments, the predictions made by the ML module 233 are based on data from the semiconductor fab. For example, this information may be based on data from the sensor module 229 (e.g., FTIR or mass spectra) and/or predicted based on information from the semiconductor fab (e.g., which tools, materials, and/or processes are being used). In some embodiments, the information may indicate variations in exhaust gas composition. Running a variety of PFAS-based recipes in different manufacturing tools at a semiconductor fab, intertwined with chamber cleaning and validation test runs, can result in a wide variety of fab exhaust gas compositions in system 220. For example, introduction of different amounts of additional elements for an optimal plasma process at the wafer processing equipment 223 may result in these variations.

Different exhaust gas compositions can require different abatement approaches. Therefore, the AI controller 226 may use information about the fab exhaust compositions to optimize abatement parameters at system 201 or 215. In some embodiments, the AI controller 226 can enable these different approaches by adjusting system 220 settings (e.g. gas flow, temperature, etc.) via the instruction module 236. For example, the ML model 233 may predict, based on the composition of exhaust gas being produced, that intentional addition of oxygen gas to the fluorinated exhaust gas stream will increase the efficiency of the fluorinated gas abatement reaction. In response to this prediction, the instruction module 236 may direct a gas source module (see above) to add oxygen to the exhaust stream traveling from the wafer processing equipment 223 to system 201 or 215.

In another example, the ML model 233 may determine that there is insufficient metal vapor being introduced into the mixing component 206. The ML model 233 may also diagnose a potential cause of this insufficiency (e.g., based on data from the sensor module 229). In response, the instruction module 236 can direct component(s) of system 201 to take appropriate actions. For example, the instruction module 236 direct the temperature of the metal vapor source 203 to be raised (e.g., via the heating element 211) to ensure sufficient evaporation of the metal, divert the exhaust gas stream to a mixing component connected to a second metal vapor source (not shown), or instruct that the metal in the metal vapor source 203 be replenished.

The AI controller 226 may also use the predictions of the ML model 233 to generate suggestions for, e.g., new reaction paths that may involve other co-reagent(s) and/or sorbent(s). The suggestions may be output via a user interface to be reviewed by a human expert. Predicting a large number of side reactions and potential ways to mitigate them can be calculation-intensive and may benefit from interaction between human experts and AI controller 226, e.g., using Bayesian optimization.

FIGS. 3A and 3B are cross-sectional diagrams illustrating apparatuses 301 and 302 for fluorinated gas abatement using metal vapor, according to some embodiments. The apparatuses 301 and 302 can be examples of system 201 illustrated in FIG. 2A. In particular, the apparatuses 301 and 302 illustrate examples of thermally isolated components 202 with different types of zinc vapor source 203. The thermally isolated components 202 can be heated to at least the boiling point of zinc by the heat source 211, which may include an inductive or resistive heating coil (represented by gray cylinders in FIGS. 3A-4B). The molten zinc 309 is illustrated in FIGS. 3A and 3B by a gray rectangle containing white circles representing bubbles. Dashed arrows represent the movement of gases in FIGS. 3A-4B.

In FIG. 3A, the apparatus 301 uses a boiler-style metal vapor source 203, which can include a crucible containing molten zinc 309. In FIG. 3B, the apparatus 302 uses a bubbler-style metal vapor source 203, which can include a crucible containing molten zinc 309 and a carrier gas that enters the crucible via a carrier gas channel 316. The carrier gas can be an inert gas such as nitrogen (N₂). The carrier gas may facilitate evaporation of the molten metal 309.

In some embodiments, the amount of available zinc 309 in either vapor source 203 can be continuously replenished by any technique known to persons of ordinary skill (e.g., molten metal injection, metal wire feed, or particulate (powder or granulate) metal feed). In some embodiments, unreacted zinc vapor is condensed, collected from the separation component 213, and used to replenish the molten zinc 309.

In both apparatuses 301 and 302, gaseous zinc produced in the metal vapor source 203 can travel through a channel 310 into a mixing component 206 (see FIG. 2A). Fluorinated gas and, optionally, other exhaust gases from a fluorinated gas source, such as the wafer processing equipment 223 shown in FIG. 2C, can enter the mixing component 206 through a fluorinated gas channel 314. In some embodiments, exhaust gas from the wafer processing equipment 223 or other source may be collected and/or treated prior to entering the fluorinated gas channel 314.

The fluorinated gas and zinc vapor can enter a reactor 209. In the reactor 209, the fluorinated gas and zinc vapor can react to form zinc fluoride (ZnF₂) and carbon. The reactor 209 can also include silica, which can react with the ZnF₂ to form SiF₄. The gaseous mixture of unreacted materials and products formed in the reactor 209 can travel into the separation component 213. The defluorinated exhaust gas can be separated from materials condensed in the separation component 213. The reactor 209 and separation component 213 are discussed in greater detail with respect to FIGS. 1-2B.

FIGS. 4A and 4B are cross-sectional diagrams illustrating apparatuses 401 and 402 for fluorinated gas abatement using elemental silicon, according to some embodiments. The two apparatuses 401 and 402 are similar except that apparatus 402 has a configuration that may be more compact than apparatus 401. Each apparatus 401/402 can include a reactor 209 containing SiOₓ (e.g., where x=0-0.1 or x=0.1-0.5) and a heat source 211. Each apparatus 401/402 can receive fluorinated gas from, e.g., the wafer processing equipment/fluorinated gas source 223. The fluorinated gas can enter the reactor 209 via a fluorinated gas channel 314. The fluorinated compounds can react with the SiOₓ in the reactor 209 to form SiF₄.

The resulting gaseous mixture of products and unreacted materials can pass from the reactor 209 into the separation component 213, which can include a carbon filter 415 with a cooling component 417 (represented by white cylinders) for condensation of carbon. In some embodiments, there can be a channel 412 between the reactor and separation component 213. In further embodiments, there may be a separate condensation chamber (not shown). Additionally, the carbon filter 415 and/or cooling component 417 may optionally be omitted.

The separation component 213 can also include a scrubbing material 418 for reacting with SiF₄ to form Na₂SiF₆. The scrubbing material 418 may be, e.g., NaF or NaHCO₃. The Na₂SiF₆ may be used in subsequent processes to generate higher-purity SiF₄ (e.g., by thermal decomposition) that can be used to produce fluorides and/or high-purity silicon. As discussed above with respect to FIGS. 2A and 2B, the separation component 213 may also use other scrubbing techniques or materials instead of, or in addition to, passing through NaHCO₃ or NaF. Other elements of the separation component 213 that may be included in apparatuses 401/402 are discussed in greater detail above. From the separation component 213, the defluorinated gas can exit through an outlet 425.

Experimental examples of CF₄ abatement are discussed below:
Example 1: A small quartz tube (10 mm inner diameter (ID)) tube was inserted into a 1-inch diameter quartz tube, and 5 g of Zn powder was placed directly in the smaller tube along the heated length (the portion of the tube positioned directly in the hot zone of the furnace). The quartz tubes were purged with nitrogen gas (N₂, 50 cm³) for 30 minutes. After purging, a gas mixture of 5% CF₄/95% N₂ was flown through the smaller tube at 50 cm³. The furnace temperature was ramped at maximum rate to 1100° C. in about 30 minutes. Upon surpassing the boiling point of Zn (>907° C.), the concentration of CF₄ detected by residual gas analysis (RGA) at the exhaust rapidly dropped to 1.06% of the original (98.9% abatement efficiency). As soon as the zinc source was exhausted, the CF₄ concentration rapidly increased, eventually returning to the original concentration.

Products were analyzed using secondary ion mass spectrometry (SIMS) at the surface of the smaller quartz tube. The SIMS analysis indicated the presence of zinc oxide (ZnOₓ, where x≥1) on the surface of the tube's hot zone. A black carbon-containing deposit was found between the hot zone and the exit of the tube. Additionally, analysis of the full RGA spectrum showed a mass 85 peak (SiF₃⁺), indicating the presence of SiF₄, which may be the product of a side reaction between ZnF₂ and the quartz tube (silica). A blank test run without Zn produced neither CF₄ abatement nor solid products.
Example 2: Substantially the same methods as the first experimental example were used, except that the defluorinated gas/products were passed through NaHCO₃ before exiting the quartz tube. RGA analysis of the exhaust did not show the SiF₃⁺ peak, indicating that the NaHCO₃ acted as a solid sorbent for SiF₄. Additionally, conversion of NaHCO₃ to Na₂SiF₆ was confirmed using energy dispersive X-ray (EDX) spectroscopy and scanning electron microscopy (SEM). The second experimental example resulted in 98.1% CF₄ abatement.
Example 3: A 6 mm ID quartz tube packed with Si particulate was inserted into 1-inch diameter quartz tube. The Si particulate was obtained by crushing about half of an 8-inch intrinsic Si wafer in an agate mortar down to <1 mm particles. Two quartz wool packings were used to hold the Si particulate in place. The smaller quartz tube was purged with nitrogen gas (N₂, 50 cm³) for 30 minutes. After purging, a gas mixture of 5% CF₄/95% N₂ was flown through the smaller tube at 50 cm³. The furnace temperature was ramped at maximum rate to 1100° C. in about 30 minutes. Like in Example 2, the gases/products were passed through NaHCO₃ before exiting the quartz tube. The concentration of CF₄ detected by residual gas analysis (RGA) at the exhaust indicated that >95% CF₄ abatement was achieved at 1000° C. and >99% CF₄ abatement was achieved at 1100° C. A strong SiF₃⁺ peak was detected by RGA when NaHCO₃ was not used, and no SiF₃⁺ peak was detected when NaHCO₃ was used as in Example 2. NaHCO₃ acted as a solid sorbent for SiF₄, resulting in conversion to Na₂SiF₆.

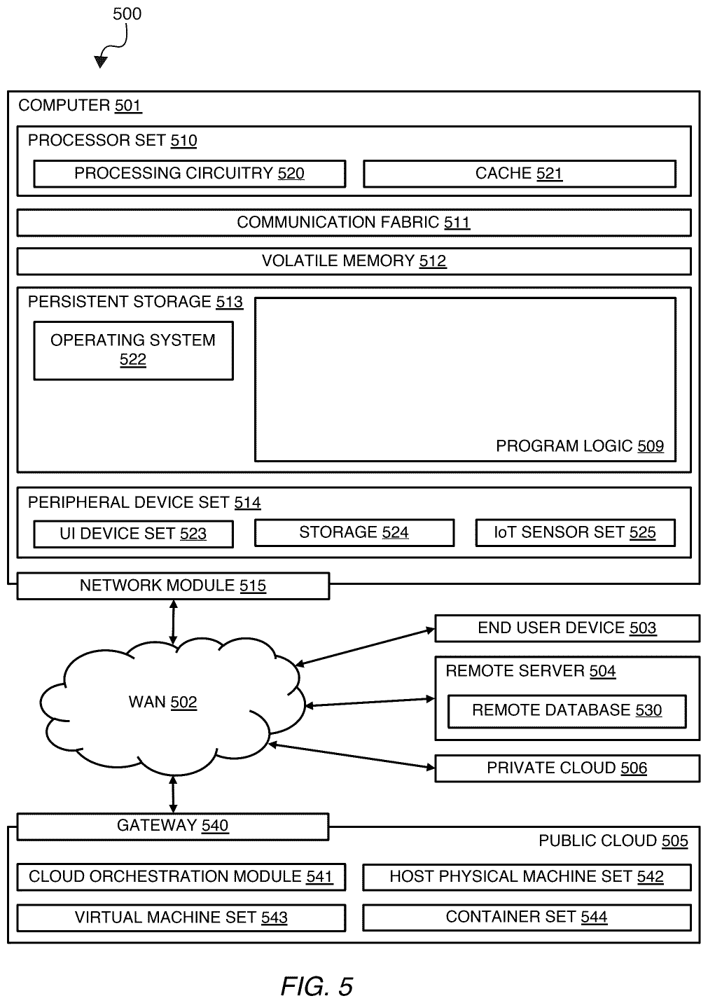

FIG. 5 is a block diagram illustrating a computing environment 500, according to some embodiments. Computing environment 500 contains an example of a program logic 509 for the execution of at least some of the computer code involved in performing the inventive methods, such as using an AI-based controller 226 (FIG. 2B) for fluorinated gas abatement. The program logic 509 may also monitor and generate instructions for fluorinated gas abatement in a semiconductor processing environment. In addition to block 509, computing environment 500 includes, for example, computer 501, wide area network (WAN) 502, end user device (EUD) 503, remote server 504, public cloud 505, and private cloud 506. In this embodiment, computer 501 includes processor set 510 (including processing circuitry 520 and cache 521), communication fabric 511, volatile memory 552, persistent storage 513 (including operating system 522 and block 509, as identified above), peripheral device set 514 (including user interface (UI), device set 523, storage 524, and Internet of Things (IoT) sensor set 525), and network module 515. Remote server 504 includes remote database 530. Public cloud 505 includes gateway 540, cloud orchestration module 541, host physical machine set 542, virtual machine set 543, and container set 544.

COMPUTER 501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network, or querying a database, such as remote database 530. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically computer 501, to keep the presentation as simple as possible. Computer 501 may be located in a cloud, even though it is not shown in a cloud in FIG. 1. On the other hand, computer 501 is not required to be in a cloud except to any extent as may be affirmatively indicated.

PROCESSOR SET 510 includes one, or more, computer processors of any type now known or to be developed in the future. Processing circuitry 520 may be distributed over multiple packages, for example, multiple, coordinated integrated circuit chips. Processing circuitry 520 may implement multiple processor threads and/or multiple processor cores. Cache 521 is memory that is located in the processor chip package(s) and is typically used for data or code that should be available for rapid access by the threads or cores running on processor set 510. Cache memories are typically organized into multiple levels depending upon relative proximity to the processing circuitry. Alternatively, some, or all, of the cache for the processor set may be located “off chip.” In some computing environments, processor set 510 may be designed for working with qubits and performing quantum computing.

Computer readable program instructions are typically loaded onto computer 501 to cause a series of operational steps to be performed by processor set 510 of computer 501 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 521 and the other storage media discussed below. The program instructions, and associated data, are accessed by processor set 510 to control and direct performance of the inventive methods. In computing environment 500, at least some of the instructions for performing the inventive methods may be stored in block 509 in persistent storage 513.

COMMUNICATION FABRIC 511 is the signal conduction paths that allow the various components of computer 501 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 512 is any type of volatile memory now known or to be developed in the future. Examples include dynamic type random access memory (RAM) or static type RAM. Typically, the volatile memory is characterized by random access, but this is not required unless affirmatively indicated. In computer 501, the volatile memory 512 is located in a single package and is internal to computer 501, but, alternatively or additionally, the volatile memory may be distributed over multiple packages and/or located externally with respect to computer 501.

PERSISTENT STORAGE 513 is any form of non-volatile storage for computers that is now known or to be developed in the future. The non-volatility of this storage means that the stored data is maintained regardless of whether power is being supplied to computer 501 and/or directly to persistent storage 513. Persistent storage 513 may be a read only memory (ROM), but typically at least a portion of the persistent storage allows writing of data, deletion of data and re-writing of data. Some familiar forms of persistent storage include magnetic disks and solid state storage devices. Operating system 522 may take several forms, such as various known proprietary operating systems or open source Portable Operating System Interface type operating systems that employ a kernel. The code included in block 509 typically includes at least some of the computer code involved in performing the inventive methods.

PERIPHERAL DEVICE SET 514 includes the set of peripheral devices of computer 501. Data communication connections between the peripheral devices and the other components of computer 501 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 523 may include components such as a display screen, speaker, microphone, wearable devices (such as goggles and smart watches), keyboard, mouse, printer, touchpad, game controllers, and haptic devices. Storage 524 is external storage, such as an external hard drive, or insertable storage, such as an SD card. Storage 524 may be persistent and/or volatile. In some embodiments, storage 524 may take the form of a quantum computing storage device for storing data in the form of qubits. In embodiments where computer 501 is required to have a large amount of storage (for example, where computer 501 locally stores and manages a large database) then this storage may be provided by peripheral storage devices designed for storing very large amounts of data, such as a storage area network (SAN) that is shared by multiple, geographically distributed computers. IoT sensor set 525 is made up of sensors that can be used in Internet of Things applications. For example, one sensor may be a thermometer and another sensor may be a motion detector.

NETWORK MODULE 515 is the collection of computer software, hardware, and firmware that allows computer 501 to communicate with other computers through WAN 502. Network module 515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 515 are performed on the same physical hardware device. In other embodiments (for example, embodiments that utilize software-defined networking (SDN)), the control functions and the forwarding functions of network module 515 are performed on physically separate devices, such that the control functions manage several different network hardware devices. Computer readable program instructions for performing the inventive methods can typically be downloaded to computer 501 from an external computer or external storage device through a network adapter card or network interface included in network module 515.

WAN 502 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 503 is any computer system that is used and controlled by an end user (for example, a customer of an enterprise that operates computer 501), and may take any of the forms discussed above in connection with computer 501. EUD 503 typically receives helpful and useful data from the operations of computer 501. For example, in a hypothetical case where computer 501 is designed to provide a recommendation to an end user, this recommendation would typically be communicated from network module 515 of computer 501 through WAN 502 to EUD 503. In this way, EUD 503 can display, or otherwise present, the recommendation to an end user. In some embodiments, EUD 503 may be a client device, such as thin client, heavy client, mainframe computer, desktop computer and so on.

REMOTE SERVER 504 is any computer system that serves at least some data and/or functionality to computer 501. Remote server 504 may be controlled and used by the same entity that operates computer 501. Remote server 504 represents the machine(s) that collect and store helpful and useful data for use by other computers, such as computer 501. For example, in a hypothetical case where computer 501 is designed and programmed to provide a recommendation based on historical data, then this historical data may be provided to computer 501 from remote database 530 of remote server 504.

PUBLIC CLOUD 505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 505 is performed by the computer hardware and/or software of cloud orchestration module 541. The computing resources provided by public cloud 505 are typically implemented by virtual computing environments that run on various computers making up the computers of host physical machine set 542, which is the universe of physical computers in and/or available to public cloud 505. The virtual computing environments (VCEs) typically take the form of virtual machines from virtual machine set 543 and/or containers from container set 544. It is understood that these VCEs may be stored as images and may be transferred among and between the various physical machine hosts, either as images or after instantiation of the VCE. Cloud orchestration module 541 manages the transfer and storage of images, deploys new instantiations of VCEs and manages active instantiations of VCE deployments. Gateway 540 is the collection of computer software, hardware, and firmware that allows public cloud 505 to communicate through WAN 502.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 506 is similar to public cloud 505, except that the computing resources are only available for use by a single enterprise. While private cloud 506 is depicted as being in communication with WAN 502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 505 and private cloud 506 are both part of a larger hybrid cloud.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A process, comprising:
receiving fluorinated gas at a reactor containing a compound of the formula SiOₓ, wherein 0≤x≤2;
obtaining a gaseous mixture formed at an elevated temperature in the reactor; and
removing silicon tetrafluoride (SiF₄) from the gaseous mixture.

2. The process of claim 1, wherein 0≤x≤0.1.

3. The process of claim 1, wherein the elevated temperature is between about 960° C. and 1100° C.

4. The process of claim 1, wherein the removing the SiF₄ comprises wet scrubbing.

5. The process of claim 1, wherein the removing the SiF₄ comprises passing the gaseous mixture through sodium bicarbonate or sodium fluoride to form sodium fluorosilicate.

6. The process of claim 5, further comprising using the sodium fluorosilicate to produce a fluoride.

7. The process of claim 5, further comprising using sodium fluorosilicate to produce high-purity silicon.

8. The process of claim 1, wherein the compound of the formula SiOₓ comprises silica.

9. The process of claim 8, wherein the reactor also contains zinc vapor.

10. The process of claim 1, further comprising:
monitoring abatement of the fluorinated gas using at least one sensor;
generating a machine-learning model for modeling the abatement; and
based on the monitoring and the machine-learning model, generating instructions for optimizing the abatement.

11. An apparatus, comprising:
a reactor containing a compound of the formula SiOₓ, wherein 0≤x≤2;
a component for receiving fluorinated gas at the reactor;
a heating element for heating the compound of the formula SiOₓ and the fluorinated gas in the reactor; and
a separation component for removing silicon tetrafluoride (SiF₄) from a gaseous mixture formed in the reactor.

12. The apparatus of claim 11, wherein 0≤x≤0.1.

13. The apparatus of claim 11, wherein the heating element heats the reactor to a temperature between about 960° C. and 1100° C.

14. The apparatus of claim 11, wherein the separation component comprises a scrubber containing sodium bicarbonate or sodium fluoride.

15. The apparatus of claim 11, wherein 1.5≤x≤2.

16. The apparatus of claim 15, further comprising a metal vapor source.

17. The apparatus of claim 16, further comprising a mixing component for mixing the metal vapor with the fluorinated gas.

18. The apparatus of claim 11, wherein the fluorinated gas is an exhaust gas from semiconductor processing.

19. The apparatus of claim 11, wherein the apparatus is monitored by at least one sensor in communication with a computing device.

20. The apparatus of claim 19, wherein the computing device is configured to:
generate a machine-learning model for modeling a process of fluorinated gas abatement; and
based on the monitoring and the machine-learning model, generate instructions for the apparatus.

21. A system, comprising:
an apparatus, comprising:
a reactor containing a compound of the formula SiOₓ, wherein 0≤x≤2;
a component for receiving fluorinated gas at the reactor;
a heating element for heating the compound of the formula SiOₓ and the fluorinated gas in the reactor; and
a separation component for removing silicon tetrafluoride (SiF₄) from a gaseous mixture formed in the reactor.

22. A process of semiconductor manufacturing, comprising:
defluorinating exhaust gas using a process comprising:
receiving fluorinated gas at a reactor containing a compound of the formula SiOₓ, wherein 0≤x≤2;
obtaining a gaseous mixture formed at an elevated temperature in the reactor; and
removing silicon tetrafluoride (SiF₄) from the gaseous mixture.

23. The process of claim 22, wherein the removing the SiF₄ comprises passing the gaseous mixture through sodium bicarbonate or sodium fluoride.

24. A system for semiconductor manufacturing, comprising:
a set of components configured to carry out a process of fluorinated gas abatement, the process comprising:
providing a reactor containing a compound of the formula SiOₓ, wherein 0≤x≤2;
receiving, at the reactor, fluorinated gas;
obtaining a gaseous mixture formed at an elevated temperature in the reactor; and
removing silicon tetrafluoride (SiF₄) from the gaseous mixture.

25. The system of claim 24, further comprising:
a computing device configured to generate instructions for at least one component from the set of components based on a machine-learning model for modeling the process.
